(19) United States
(12) Patent Application Publication
(10) Pub. No.: US 2025/0007521 A1
(43) Pub. Date: Jan. 2, 2025

(54) METHODS AND APPARATUS FOR MULTI-PHASE CLOCK GENERATION

(71) Applicant: Texas Instruments Incorporated, Dallas, TX (US)

(72) Inventors: Sang Yong Lee, Phoenix, AZ (US); Uzair Mohammed, Chandler, AZ (US); Ahmed Hashim, Gilbert, AZ (US)

(21) Appl. No.: 18/215,716

(22) Filed: Jun. 28, 2023

(51) Int. Cl. H03L 7/07; H03L 7/081

(52) U.S. Cl. CPC H03L 7/07; H03L 7/0816

(57) ABSTRACT

An example apparatus includes: first clock generation circuitry including: interlock circuitry having a terminal; reference clock generation circuitry having a first terminal and a second terminal, the first terminal of the reference clock generation circuitry coupled to the terminal of the interlock circuitry; first duty cycle replication circuitry having a first terminal and a second terminal, the first terminal of the first duty cycle replication circuitry coupled to the second terminal of the reference clock generation circuitry; and buffer circuitry having a first terminal and a second terminal, the first terminal of the buffer circuitry coupled to the second terminal of the first duty cycle replication circuitry; and second clock generation circuitry including: detection circuitry having a first terminal and a second terminal, the first terminal of the detection circuitry coupled to the second terminal of the buffer circuitry; second detection circuitry having a first terminal and a second terminal.

### TECHNICAL FIELD

This description relates generally to clock generation and, more particularly, to methods and apparatus for multi-phase clock generation.

### BACKGROUND

As circuitry continues to become increasingly complex, incentives to create flexible clock generation circuitry continue to increase. In some devices, clock generation circuitry needs to be capable of generating a plurality of clock signals. Some such clock generation circuitry generates each of the plurality of clock signals with different phases.

### SUMMARY

For methods and apparatus for multi-phase clock generation, an example apparatus includes first clock generation circuitry including: interlock circuitry having a terminal; reference clock generation circuitry having a first terminal and a second terminal, the first terminal of the reference clock generation circuitry coupled to the terminal of the interlock circuitry; first duty cycle replication circuitry having a first terminal and a second terminal, the first terminal of the first duty cycle replication circuitry coupled to the second terminal of the reference clock generation circuitry; and buffer circuitry having a first terminal and a second terminal, the first terminal of the buffer circuitry coupled to the second terminal of the first duty cycle replication circuitry; and second clock generation circuitry including: detection circuitry having a first terminal and a second terminal, the first terminal of the detection circuitry coupled to the second terminal of the buffer circuitry; second detection circuitry having a first terminal and a second terminal, the first terminal of the second detection circuitry coupled to the second terminal of the detection circuitry; and second duty cycle replication circuitry having a terminal coupled to the second terminal of the second detection circuitry.

### BRIEF DESCRIPTION OF THE DRAWINGS

FIG. 1 is a block diagram of an example chain power supply in which example power converter circuitry utilizes example primary and secondary clock generation circuitry to supply power.

FIG. 2 is a block diagram of an example of the primary clock generation circuitry of FIG. 1 including example interlock circuitry, example reference clock generation circuitry, and example duty cycle replication circuitry configured to generate a clock signal.

FIG. 3 is a block diagram of an example of the secondary clock generation circuitry of FIG. 1 including example duty cycle replication circuitry to generate a phase shifted clock signal.

FIG. 4 is a schematic diagram of an example implementation of the interlock circuitry of FIG. 2.

FIG. 5 is a schematic diagram of an example implementation of the reference clock generation circuitry of FIG. 2.

FIG. 6 is a schematic diagram of an example implementation of the duty cycle replication circuitry of FIGS. 2 and 3.

FIG. 7 is a timing diagram of an example operation of the primary and secondary clock generation circuitries of FIGS. 1-3.

FIGS. 8A and 8B form a flowchart representative of example operations that may be executed, instantiated, and/or performed by the primary and secondary clock generation circuitry of FIGS. 1-3 to generate a plurality of clock signals of different phases.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

Methods of generating clock signals continue to advance. Some clock generation circuitries utilize electrical characteristics of components, such as resistors, capacitors, and/or crystals, to generate a clock signal. Some applications are capable of using relatively simple methods of clock generation, such as an oscillation between a resistor and capacitor. While other applications need more complex methods of clock generation. Such applications include relatively high speed processor circuitry, safety circuitry, switching power supplies, etc.

As electronics continue to advance, designers are incentivized to use increasingly complex clock generation circuitry capable of generating a plurality of clock signals. Some instances of clock generation circuitries need a plurality of clock signals. In such applications, designers typically use timing techniques, such as clock division or phase shifting, to generate the plurality of clock signals from a single clock signal. However, most timing techniques are not adjustable and need to be designed specific to a device, such as a set amount of clock signals or a predetermined duty cycle.

Examples described herein include methods and apparatus for multi-phase clock generation circuitry capable of dynamically adjusting clock signal duty cycles. In some described examples, primary clock generation circuitry is coupled in series with one or more instances of secondary clock generation circuitry creating a digitally locked loop. The digitally locked loop allows the clock generation circuitry to modify a duty cycle of each clock signal to compensate for the number of secondary clock generation circuitries. The primary clock generation circuitry and each of the one or more instances of the secondary clock generation circuitry generate a clock signal. The primary clock generation circuitry modifies a duty cycle of a first clock signal to account for the one or more instances of the secondary clock generation circuitry. The secondary clock generation circuitry generates a clock signal by replicating the duty cycle of the first clock signal. Further, the secondary clock generation circuitry syncs the falling edge of an input clock signal to a rising edge of an output clock signal. Advantageously, the primary clock generation circuitry adjusts the duty cycle of the plurality of clock signals to compensate for a plurality of secondary clock generation circuitries.

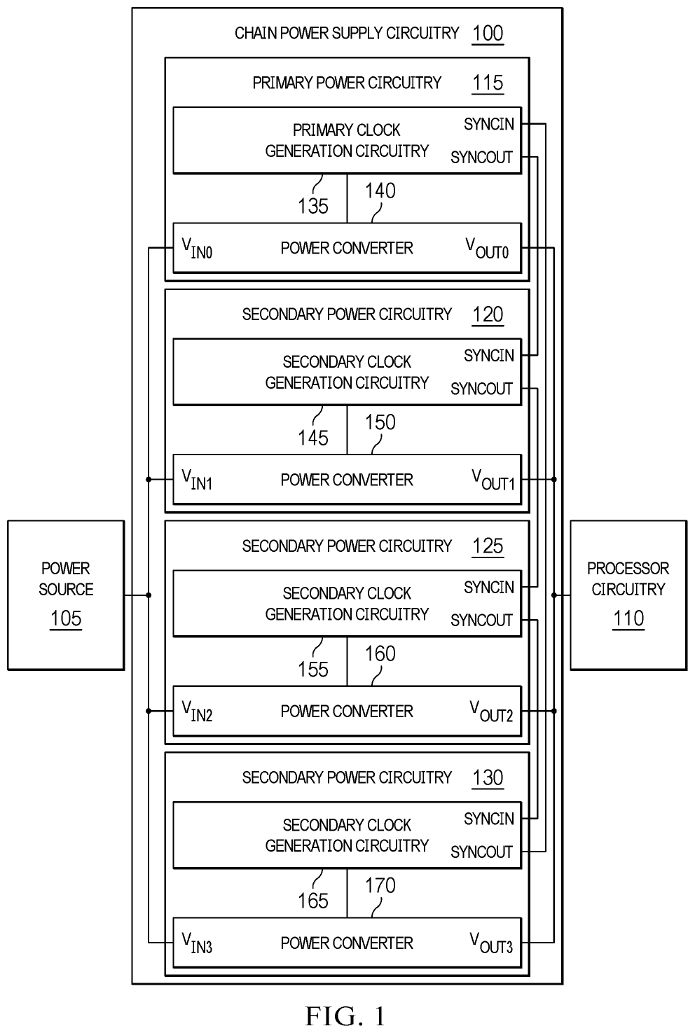

FIG. 1 is a block diagram of an example chain power supply 100 configured to supply power from an example power source 105 to example processor circuitry 110. In the example of FIG. 1, the chain power supply 100 includes example primary power circuitry 115, first example secondary power circuitry 120, second example secondary power circuitry 125, and third example secondary power circuitry 130. The chain power supply 100 uses multi-phase clock generation to supply continuous power to the processor circuitry 110.

In the example of FIG. 1, the processor circuitry 110 is programmable circuitry configured to execute, instantiate, and/or perform example machine readable instructions and/or perform the example operations. In some examples, the processor circuitry 110 is configured to operate based on a magnitude of power supplied by the chain power supply 100. In such examples, the chain power supply circuitry 100 supplies power from all of the power circuitries 115-130 to increase performance of the processor circuitry 100. In other examples, the chain power supply circuitry 100 supplies power using the primary power circuitry 115 and one or more of the secondary power circuitries 120-130. For example, one or more of the secondary power circuitries are no longer operational. In such examples, the processor circuitry 110 remains capable of performing operations, but the processor circuitry may be limited due to a decrease in power supplied by the chain power supply circuitry 100. Although in the example of FIG. 1, the chain power supply 100 is configured to supply power to the processor circuitry 110, the chain power supply 100 may supply power to alternate external circuitry.

The primary power circuitry 115 is coupled to the power source 105, the processor circuitry 110, and the secondary power circuitries 120-130. In the example of FIG. 1, the primary power circuitry 115 includes example primary clock generation circuitry 135 and a first example power converter 140. The primary power circuitry 115 converts and/or regulates power from the power source 105 based on a clock signal from the primary clock generation circuitry 135. The primary power circuitry 115 supplies power to the processor circuitry 110.

The first secondary power circuitry 120 is coupled to the power source 105, the processor circuitry 110, and the power circuitries 115, 125, and 130. In the example of FIG. 1. the first secondary power circuitry 120 includes first example secondary clock generation circuitry 145 and a second example power converter 150. The first secondary power circuitry 120 converts and/or regulates power from the power source 105 based on a clock signal from the first secondary clock generation circuitry 145. The first secondary power circuitry 120 supplies power to the processor circuitry 110.

The second secondary power circuitry 125 is coupled to the power source 105, the processor circuitry 110, and the power circuitries 115, 120, and 130. In the example of FIG. 1, the second secondary power circuitry 125 includes second example secondary clock generation circuitry 155 and a third example power converter 160. The second secondary power circuitry 125 is configured similar to the first secondary power circuitry 120.

The third secondary power circuitry 130 is coupled to the power source 105, the processor circuitry 110, and the power circuitries 115-125. In the example of FIG. 1, the third secondary power circuitry 130 includes third example secondary clock generation circuitry 165 and a fourth example power converter 170. The third secondary power circuitry 130 is configured similar to the secondary power circuitries 120 and 125.

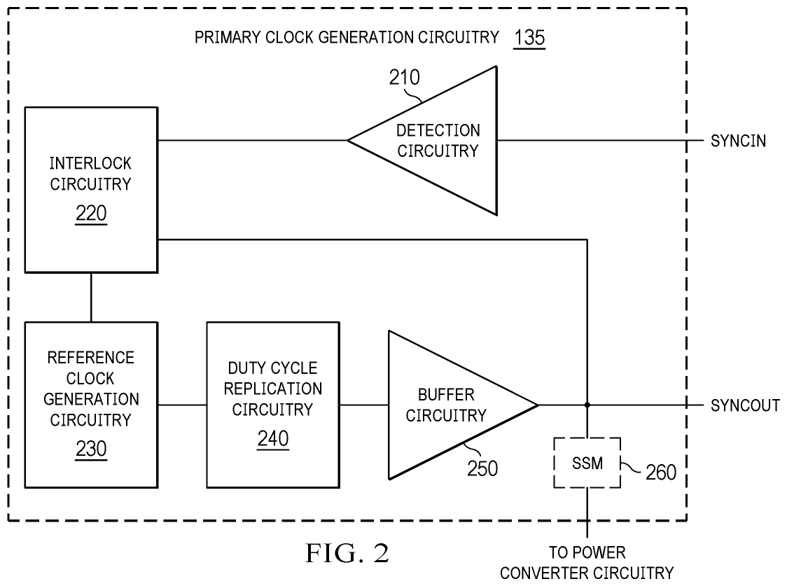

The primary clock generation circuitry 135 has a first terminal (SYNCOUT) coupled to the first secondary power circuitry 120. The primary clock generation circuitry 135 has a second terminal (SYNCIN) coupled to the third secondary power circuitry 130. The primary clock generation circuitry 135 has a third terminal coupled to the first power converter 140. The primary clock generation circuitry 135 receives an input clock signal from the third secondary power circuitry 130. The primary clock generation circuitry 135 generates an interlock voltage based on the input clock signal and an output clock signal of the primary clock generation circuitry 135. The primary clock generation circuitry 135 generates a reference clock based on the interlock voltage. The primary clock generation circuitry 135 replicates a duty cycle of the reference clock to generate the output clock signal. The primary clock generation circuitry 135 supplies the output clock signal to the first secondary power circuitry 120. The primary clock generation circuitry 135 may supply the output clock to the first power converter 140. In some examples, the primary clock generation circuitry 135 uses spread spectrum modulation (SSM) to generate an internal clock signal based on the output clock signal. In such examples, the primary clock generation circuitry 135 supplies the internal clock signal to the first power converter 140. An example implementation of the primary clock generation circuitry 135 is described in further detail in connection with FIG. 2, below.

The first power converter 140 has a first terminal coupled to the power source 105. The first power converter 140 has a second terminal coupled to the primary clock generation circuitry 135. The first power converter 140 has a third terminal coupled to the processor circuitry 110 and the secondary power circuitries 120-130. The first power converter 140 converts and/or regulates power from the power source 105. The first power converter 140 may use a phase of a clock signal from the primary clock generation circuitry 135 to supply power to the processor circuitry 110. In some examples, the first power converter 140 may be a switching power converter, regulator circuitry, etc.

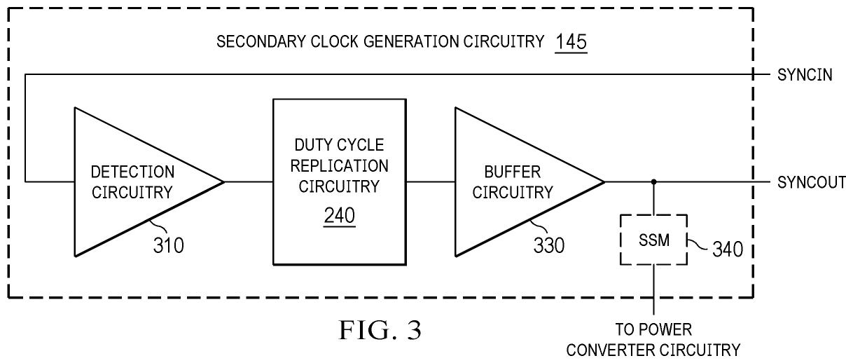

The first secondary clock generation circuitry 145 has a first terminal (SYNCIN) coupled to the primary clock generation circuitry 135 of the primary power circuitry 115. The first secondary clock generation circuitry 145 has a second terminal (SYNCOUT) coupled to the second secondary power circuitry 125. The first secondary clock generation circuitry 145 receives an input clock signal from the primary clock generation circuitry 135. The first secondary clock generation circuitry 145 generates an output clock signal by replicating a duty cycle of the input clock signal. The first secondary clock generation circuitry 145 generates the output clock signal to have a rising edge at approximately the same time as a falling edge of the input clock signal from the primary clock generation circuitry 135. The first secondary clock generation circuitry 145 supplies the output clock signal to the second secondary power circuitry 125. The first secondary clock generation circuitry 145 may supply the output clock to the second power converter 150. In some examples, the first secondary clock generation circuitry 145 uses SSM to generate an internal clock signal based on the output clock signal. In such examples, the first secondary clock generation circuitry 145 supplies the internal clock signal to the second power converter 150. An example implementation of the first secondary clock generation circuitry 145 is described in further detail in connection with FIG. 3, below.

The second power converter 150 has a first terminal coupled to the power source 105. The second power converter 150 has a second terminal coupled to the first secondary clock generation circuitry 145. The second power converter 150 has a third terminal coupled to the processor circuitry 110 and the power circuitries 115, 125, and 130. The second power converter 150 converts and/or regulates power from the power source 105. The second power converter 150 may use a phase of a clock signal from the first secondary clock generation circuitry 145 to supply power to the processor circuitry 110. In some examples, the second power converter 150 may be a switching power converter, regulator circuitry, etc.

The second secondary clock generation circuitry 155 has a first terminal coupled to the first secondary clock generation circuitry 145 of the first secondary power circuitry 120. The second secondary clock generation circuitry 155 has a second terminal coupled to the third secondary power circuitry 130. The second secondary clock generation circuitry 155 is configured similar to the first secondary clock generation circuitry 145.

The third power converter 160 has a first terminal coupled to the power source 105. The third power converter 160 has a second terminal coupled to the second secondary clock generation circuitry 155. The third power converter 160 has a third terminal coupled to the processor circuitry 110. The third power converter 160 is configured similar to the power converters 140 and 150.

The third secondary clock generation circuitry 165 has a first terminal coupled to the second secondary clock generation circuitry 155 of the second secondary power circuitry 125. The third secondary clock generation circuitry 165 has a second terminal coupled to the primary clock generation circuitry 135 of the primary power circuitry 115. The third secondary clock generation circuitry 165 is configured similar to the secondary clock generation circuitries 145 and 155.

The fourth power converter 170 has a first terminal coupled to the power source 105. The fourth power converter 170 has a second terminal coupled to the third secondary clock generation circuitry 165. The fourth power converter 170 has a third terminal coupled to the processor circuitry 110. The fourth power converter 170 is configured similar to the power converters 140, 150, and 160.

In an example startup operation, the primary clock generation circuitry 135 generates a first output clock based on an interlock voltage. The primary clock generation circuitry 135 supplies the first output clock to the first secondary clock generation circuitry 145. The first secondary clock generation circuitry 145 replicates and phase shifts the first output clock to generate a second output clock. A duty cycle of the second output clock is approximately equal to a duty cycle of the first output clock from the primary clock generation circuitry 135. A rising edge of the second output clock occurs at approximately the same time as a falling edge of the first output clock from the primary clock generation circuitry 135. The first secondary clock generation circuitry 145 supplies the second output clock to the second secondary clock generation circuitry 155.

In such example operations, the second secondary clock generation circuitry 155 replicates and phase shifts the second output clock to generate a third output clock. A duty cycle of the third output clock is approximately equal to the duty cycles of the output clocks from the clock generation circuitries 135 and 145. A rising edge of the third output clock occurs at approximately the same time as a falling edge of the second output clock from the first secondary clock generation circuitry 145. The second secondary clock generation circuitry 155 supplies the third output clock to the third secondary clock generation circuitry 165. The third secondary clock generation circuitry 165 replicates and phase shifts the third output clock to generate a fourth output clock. A duty cycle of the fourth output clock is approximately equal to the duty cycles of the output clocks from the clock generation circuitries 135, 145, and 155. A rising edge of the fourth output clock occurs at approximately the same time as a falling edge of the third output clock from the second secondary clock generation circuitry 155. The third secondary clock generation circuitry 165 supplies the fourth output clock to the primary clock generation circuitry 135.

In such example operations, the primary clock generation circuitry 135 compares the falling edge of the fourth output clock to a rising edge of the first output clock. The primary clock generation circuitry 135 modifies the interlock voltage when the falling edge of the fourth output clock occurs before the rising edge of the first output clock. The primary clock generation circuitry 135 generates the first output clock using the modified interlock voltage. Modifying the interlock voltage changes the duty cycle of the first output clock, which determines the duty cycle of the output clocks of the secondary clock generation circuitries 145, 155, and 165. The secondary clock generation circuitries 145, 155, and 165 generate output clocks using the modified duty cycle. The primary clock generation circuitry 135 continues to modify the interlock voltage until a rising edge of the fourth output clock from the third secondary clock generation circuitry 165 occurs approximately at the same time as a rising edge of the reference clock.

Advantageously, the primary clock generation circuitry 135 dynamically adjusts a duty cycle of the clocks generated by the clock generation circuitries 135, 145, 155, and 165. Advantageously, the primary clock generation circuitry 135 may be chained to one or more instances of the secondary clock generation circuitries 145, 155, and/or 165 without needing to be modified or adjusted. Advantageously, the primary clock generation circuitry 135 may correct a duty cycle of the output clocks to compensate for one or more of the secondary clock generation circuitries 145, 155, and/or 165 not operating. Advantageously, one or more of the power circuitries 115-130 may continue to supply power to the processor circuitry 110 despite one or more of the power circuitries being inoperable (e.g., damaged, turned off, disabled, etc.).

FIG. 2 is a block diagram of an example of the primary clock generation circuitry 135 of FIG. 1. In the example of FIG. 2, the primary clock generation circuitry 135 includes example detection circuitry 210, example interlock circuitry 220, example reference clock generation circuitry 230, example duty cycle replication circuitry 240, example buffer circuitry 250, and example SSM circuitry 260. The primary clock generation circuitry 135 generates an output clock signal (SYNCOUT) based on an input clock signal (SYNCIN) and a reference clock.

The detection circuitry 210 has an input coupled to the input clock signal. The detection circuitry 210 has an output coupled to the interlock circuitry 220. The detection circuitry 210 isolates the interlock circuitry 220 from circuitry supplying the input clock signal. The detection circuitry 210 buffers the input clock signal. For example, the detection circuitry 210 increases a drive strength of the input clock signal. In some examples, the detection circuitry 210 detects a failure of secondary clock generation circuitry (e.g., the secondary clock generation circuitries 145, 155, and/or 165). In such examples the detection circuitry 210 determines the failure of secondary clock generation circuitry upon failing to receive the input clock signal. The detection circuitry 210 supplies the input clock signal to the interlock circuitry 220.

The interlock circuitry 220 has a first terminal coupled to the detection circuitry 210. The interlock circuitry 220 has a second terminal coupled to the reference clock generation circuitry 230. The interlock circuitry 220 has a third terminal coupled to the buffer circuitry 250 and the SSM circuitry 260. The interlock circuitry 220 receives the input clock signal from the detection circuitry 210. The interlock circuitry 220 receives the output clock signal from the buffer circuitry 250. The interlock circuitry 220 compares the output clock signal to the input clock signal.

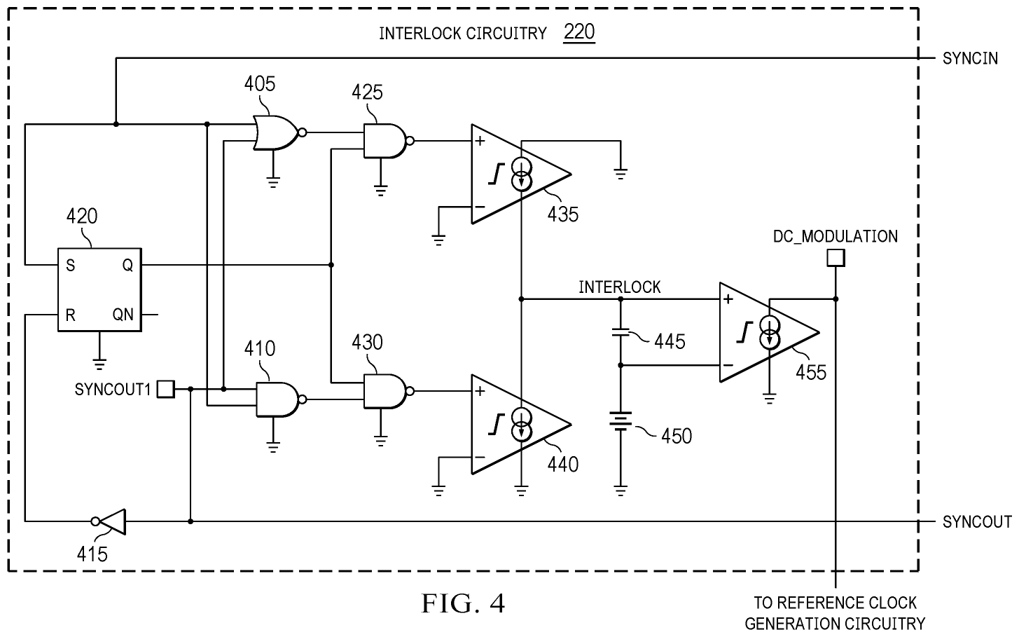

The interlock circuitry 220 determines an interlock voltage representative of a duty cycle of the output clock signal. The interlock circuitry 220 modifies the interlock voltage when a rising edge of the output clock signal does not occur at approximately the same time as a falling edge of the input clock signal. In some examples, the interlock circuitry 220 modifies the interlock voltage to increase a duty cycle of the output clock signal. In such examples, the interlock circuitry 220 no longer modifies the interlock voltage when the duty cycle of the output clock signal causes the falling edge of the input clock signal to occur at a time approximately equal to the rising edge of the output clock signal. The interlock circuitry 220 sources a current from the reference clock generation circuitry 230 based on the interlock voltage. An example implementation of the interlock circuitry 220 is described in connection with FIG. 4, below.

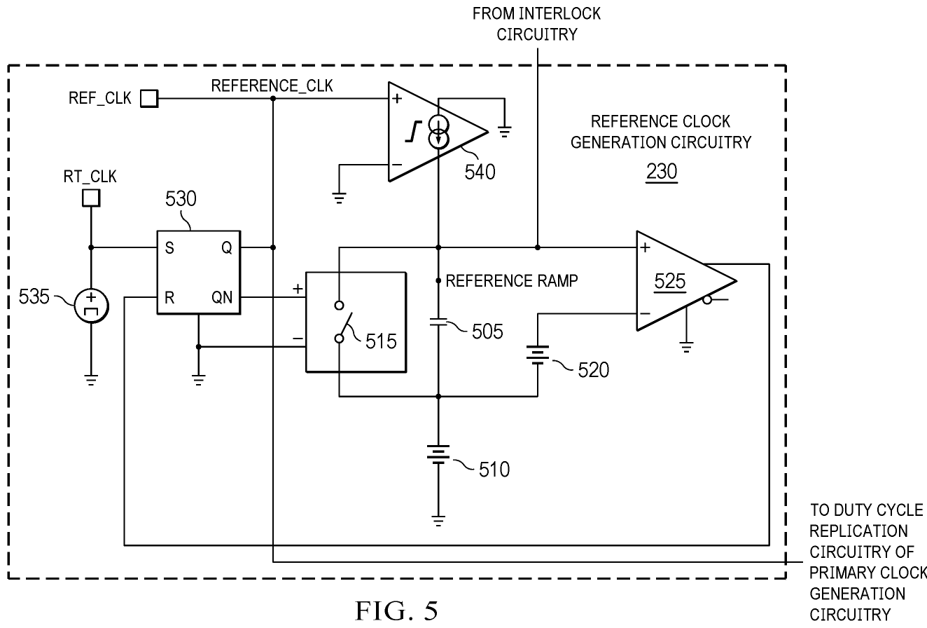

The reference clock generation circuitry 230 has a first terminal coupled to the interlock circuitry 220. The reference clock generation circuitry 230 has a second terminal coupled to the duty cycle replication circuitry 240. In some examples, the interlock circuitry 220 sources a current from the reference clock generation circuitry 230 based on the interlock voltage. The reference clock generation circuitry 230 generates a reference clock signal based on a reference ramp signal. The interlock circuitry 220 controls the duty cycle of the reference clock signal by modifying a ramp time of the reference ramp signal. A duration of a decrease of the reference ramp signal determines the duty cycle of the reference clock signal. The interlock circuitry 220 increases the duty cycle of the reference clock signal by increasing a duration of time in which the reference ramp signal decreases. The reference clock generation circuitry 230 supplies the reference clock signal to the duty cycle replication circuitry 240. An example implementation of the reference clock generation circuitry 230 is described in connection with FIG. 5, below.

The duty cycle replication circuitry 240 has a first terminal coupled to the reference clock generation circuitry 230. The duty cycle replication circuitry 240 has a second terminal coupled to the buffer circuitry 250. The duty cycle replication circuitry 240 receives the reference clock signal from the reference clock generation circuitry 230. The duty cycle replication circuitry 240 generates an output clock signal by replicating the duty cycle of the reference clock signal. The duty cycle replication circuitry 240 syncs a rising edge of the output clock signal to a falling edge of the reference clock signal. For example, the output clock signal has a 10 percent duty cycle when the duty cycle of the reference clock signal is 10 percent. In such an example, the rising edge of the output clock signal occurs at approximately the same time as a falling edge of the reference clock signal. The duty cycle replication circuitry 240 supplies the output clock signal to the buffer circuitry 250. Advantageously, the duty cycle replication circuitry 240 phase shifts the output clock signal from the reference clock signal by synchronizing rising edges of the output clock signal to falling edges of the reference clock signal.

The buffer circuitry 250 has an input coupled to the duty cycle replication circuitry 240. The buffer circuitry 250 has an output coupled to the interlock circuitry 220 and the SSM circuitry 260. The buffer circuitry 250 receives the output clock signal from the duty cycle replication circuitry 240. The buffer circuitry 250 buffers the output clock signal. The buffer circuitry 250 isolates the duty cycle replication circuitry 240 from circuitry coupled to the output of the buffer circuitry 250. The buffer circuitry 250 supplies the output clock signal to the interlock circuitry 220 and the SSM circuitry 260.

The SSM circuitry 260 has a first terminal coupled to the interlock circuitry 220 and the buffer circuitry 250. The SSM circuitry 260 has a second terminal configured to be coupled to the first power converter 140 of FIG. 1. The SSM circuitry 260 applies spread spectrum modulations techniques to the output clock signal. In some examples, the SSM circuitry 260 increases noise immunity by increasing peaks at the target frequency of the output clock signal. In some examples, the SSM circuitry 260 may be modified or removed from the primary clock generation circuitry 135. The SSM circuitry 260 is configured to supply the output clock signal to the first power converter 140.

FIG. 3 is a block diagram of an example of the secondary clock generation circuitries 145, 155, and/or 165 of FIG. 1. In the example of FIG. 3, the secondary clock generation circuitry 145 includes the duty cycle replication circuitry 240 of FIG. 2, example detection circuitry 310, example buffer circuitry 330, and example SSM circuitry 340. The secondary clock generation circuitry 145 generates an output clock signal (SYNCOUT) based on an input clock signal (SYNCIN) from one of the primary clock generation circuitry 135 of FIGS. 1 and 2 or another one of the secondary clock generation circuitries 155 or 165.

The detection circuitry 310 has an input coupled to the input clock signal. The detection circuitry 310 has an output coupled to the duty cycle replication circuitry 240. The detection circuitry 310 isolates the duty cycle replication circuitry 240 from circuitry supplying the input clock signal. The detection circuitry 310 buffers the input clock signal. For example, the detection circuitry 310 generates a replica of the input clock signal with an increased drive strength. The detection circuitry 310 supplies the input clock signal to the duty cycle replication circuitry 240.

In the example of FIG. 3, the duty cycle replication circuitry 240 has a first terminal coupled to the detection circuitry 310. The duty cycle replication circuitry 240 has a second terminal coupled to the buffer circuitry 330. The duty cycle replication circuitry 240 receives the input clock signal from the detection circuitry 310. The duty cycle replication circuitry 240 generates the output clock signal by replicating the duty cycle of the input clock signal.

The buffer circuitry 330 has an input coupled to the duty cycle replication circuitry 240. The buffer circuitry 330 has an output coupled to the SSM circuitry 340. The buffer circuitry 330 receives the output clock signal from the duty cycle replication circuitry 240. The buffer circuitry 330 buffers the output clock signal. The buffer circuitry 330 isolates the duty cycle replication circuitry 240 from circuitry coupled to the output of the buffer circuitry 330. The buffer circuitry 330 supplies the output clock signal to the SSM circuitry 340.

The SSM circuitry 340 has a first terminal coupled to the buffer circuitry 330. The SSM circuitry 340 has a second terminal configured to be coupled to the second power converter 150 of FIG. 1. The SSM circuitry 340 applies spread spectrum modulations techniques to the output clock signal. In some examples, the SSM circuitry 340 increases noise immunity by increasing peaks at the target frequency of the output clock signal. In some examples, the SSM circuitry 340 may be modified or removed from the secondary clock generation circuitry 145. The SSM circuitry 340 is configured to supply the output clock signal to the second power converter 150.

FIG. 4 is a schematic diagram of an example implementation of the interlock circuitry 220 of FIG. 2. In the example of FIG. 2, the interlock circuitry 220 includes a first example logic gate 405, a second example logic gate 410, an example inverter 415, an example logic device 420, a third example logic gate 425, a fourth example logic gate 430, a first example amplifier 435, a second example amplifier 440, an example capacitor 445, and example voltage reference 450, and a third example amplifier 455. The interlock circuitry 220 receives the input clock signal (SYNCIN) and the output clock signal (SYNCOUT). The interlock circuitry 220 determines an interlock voltage representative of a duty cycle of the output clock signal. The interlock circuitry 220 is configured to sink a current from the reference clock generation circuitry 230 of FIG. 2 based on the interlock voltage.

The first logic gate 405 has a first input coupled to the input clock signal, the second logic gate 410, and the logic device 420. The first logic gate 405 has a second input coupled to the output clock signal, the second logic gate 410, and the inverter 415. The first logic gate 405 has an output coupled to the third logic gate 425. In the example of FIG. 4, the first logic gate 405 is an XNOR gate. The first logic gate 405 compares the input clock signal to the output clock signal. Alternatively, the first logic gate 405 may be replaced and/or modified with one or more alternate logic gate(s).

The second logic gate 410 has a first input coupled to the input clock signal, the first logic gate 405, and the logic device 420. The second logic gate 410 has a second input coupled to the output clock signal, the first logic gate 405, and the inverter 415. The second logic gate 410 has an output coupled to the fourth logic gate 430. In the example of FIG. 4, the second logic gate 410 is an AND gate. The second logic gate 410 compares the input clock signal to the output clock signal. Alternatively, the second logic gate 410 may be replaced and/or modified with one or more alternate logic gate(s).

The inverter 415 has a first terminal coupled to the output clock signal and the logic gates 405 and 410. The inverter 415 has a second terminal coupled to the logic device 420. The inverter 415 inverts the output clock signal. The inverter 415 provides the inverted output clock signal to the logic device 420.

The logic device 420 has a first input coupled to the input clock signal and the logic gates 405 and 410. The logic device 420 has a second input coupled to the inverter 415. The logic device 420 has an output coupled to the logic gates 425 and 430. In the example of FIG. 4, the logic device 420 is a rising edge triggered set-reset (SR) flip-flop. The logic device 420 latches the input clock signal based on the inverted output clock signal from the inverter 415. Alternatively, the logic device 420 may be replaced and/or modified with alternate circuitry.

The third logic gate 425 has a first input coupled to the first logic gate 405. The third logic gate 425 has a second input coupled to the logic device 420 and the fourth logic gate 430. The third logic gate 425 has an output coupled to the first amplifier 435. In the example of FIG. 4, the third logic gate 425 is an AND gate. Alternatively, the third logic gate 425 may be replaced and/or modified with one or more alternate logic gate(s).

The fourth logic gate 430 has a first input coupled to the second logic gate 410. The fourth logic gate 430 has a second input coupled to the logic device 420 and the third logic gate 425. The fourth logic gate 430 has an output coupled to the second amplifier 440. In the example of FIG. 4, the fourth logic gate 430 is an AND gate. Alternatively, the fourth logic gate 430 may be replaced and/or modified with one or more alternate logic gate(s).

The first amplifier 435 has a first input coupled to the third logic gate 425. The first amplifier 435 has a second input coupled to a common potential (e.g., ground). The first amplifier 435 has a first output coupled to the common potential. The first amplifier 435 has a second output coupled to the second amplifier 440, the capacitor 445, and the third amplifier 455. The first amplifier 435 supplies a current to the second output based on the voltage of the first input. In some examples, the first amplifier 435 sources a current from the first output when a voltage of the first input is greater than a voltage of the second input. In the example of FIG. 4, the first amplifier 435 may be referred to as a transconductance (gₘ) amplifier.

The second amplifier 440 has a first input coupled to the fourth logic gate 430. The second amplifier 440 has a second input coupled to the common potential. The second amplifier 440 has a first output coupled to the first amplifier 435, the capacitor 445, and the third amplifier 455. The second amplifier 440 has a second output coupled to the common potential. The second amplifier 440 sources a current from the first output based on the voltage of the first input. In some examples, the second amplifier 440 sources a current from the first output when a voltage of the first input is greater than a voltage of the second input. In the example of FIG. 4, the second amplifier 440 may be referred to as a transconductance (gₘ) amplifier.

The capacitor 445 has a first terminal coupled to the amplifiers 435, 440, and 455. The capacitor 445 has a second terminal coupled to the voltage reference 450 and the third amplifier 455. The capacitor 445 sets the interlock voltage based on a voltage of the voltage reference 450 and current being sources and/or sunk by the amplifiers 435 and 440.

The third amplifier 455 has a first input coupled to the amplifiers 435 and 440 and the capacitor 445. The third amplifier 455 has a second input coupled to the capacitor 445 and the voltage reference 450. The third amplifier 455 has a first output configured to be coupled to the reference clock generation circuitry 230 of FIG. 2. The third amplifier 445 has a second output coupled to the common potential. The third amplifier 455 sources a current from the reference clock generation circuitry 230 based on a voltage difference between the first and second inputs of the third amplifier 455. In the example of FIG. 4, the third amplifier 455 is controlled by a voltage difference across the capacitor 445.

In example operation, the first amplifier 435 begins to supply a current to the capacitor 445 responsive to a falling edge of the input clock signal while the output clock signal is a logic low. In such an operation, the interlock voltage of the capacitor 445 increases. The first amplifier 435 does not supply current to the capacitor 445 while either of the input or output clock signals are equal to a logic high. Advantageously, the interlock voltage of the capacitor 445 increases proportional to non-overlapping time between the falling edge of the input clock signal and the rising edge of the output clock signal.

In example operation, the second amplifier 440 begins to sink a current from the capacitor 445 responsive to an overlapping duration of time where both the input clock signal and the output clock signal are a logic high. In such an operation the interlock voltage of the capacitor 445 either decreases or remains constant as current supplied by the first amplifier 435 is being sunk by the second amplifier 440. Advantageously, the second amplifier 440 prevents the interlock voltage of the capacitor 445 from increasing during overlapping duty cycles.

FIG. 5 is a schematic diagram of an example implementation of the reference clock generation circuitry 230 of FIG. 2. In the example of FIG. 5, the reference clock generation circuitry 230 includes an example capacitor 505, a first example voltage reference 510, an example switch 515, a second example voltage reference 520, a first example amplifier 525, an example logic device 530, an example clock source 535, and a second example amplifier 540. The reference clock generation circuitry 230 generates a reference clock signal with a duty cycle based on a current being sourced by the interlock circuitry 220 of FIGS. 2 and 4 and a frequency of the clock source 535.

The capacitor 505 has a first terminal coupled to the switch 515, the amplifiers 525 and 540, and adaptive to be coupled to the interlock circuitry 220. The capacitor 505 has a second terminal coupled to the voltage references 510 and 520 and the switch 515. The capacitor 505 generates a reference ramp voltage based on current being supplied to and/or sunk from the capacitor 505.

The first voltage reference 510 is coupled to the capacitor 505, the switch 515, and the second voltage reference 520. The first voltage reference 510 supplies a voltage to the capacitor 505 and the second voltage reference 520. In the example of FIG. 5, the first voltage reference 510 offsets the capacitor 505.

The switch 515 has a first terminal coupled to the capacitor 505, the amplifiers 525 and 540, and adaptive to be coupled to the interlock circuitry 220. The switch 515 has a second terminal coupled to the capacitor 505 and the voltage references 510 and 520. The switch 515 has a control terminal coupled to the logic device 530. The first terminal of the switch 515 is coupled to the second terminal of the switch 515 responsive to the switch 515 being closed by the logic device 530. The first terminal of the switch 515 is decoupled to the second terminal of the switch 515 responsive to the switch 515 being opened by the logic device 530.

The second voltage reference 520 has a first terminal coupled to the capacitor 505, the first voltage reference 510, and the switch 515. The second voltage reference 520 has a second terminal coupled to the first amplifier 525. The second voltage reference 520 supplies a voltage to the first amplifier 525. In the example of FIG. 5, the second voltage reference 520 offsets an input of the first amplifier 525.

The first amplifier 525 has a first input coupled to the capacitor 505, the switch 515, the second amplifier 540, and adaptive to be coupled to the interlock circuitry 220. The first amplifier 525 has a second input coupled to the second voltage reference 520. The first amplifier 525 has an output coupled to the logic device 530. The first amplifier 525 supplies an output voltage to the logic device 530 based on the voltage difference between the first and second inputs of the first amplifier 525. In some examples, the first amplifier 525 sets the output to a logic high when a voltage of the first input is greater than a voltage of the second input. In such examples, the first amplifier 525 sets the output to a logic low when the voltage of the first input is less than the voltage of the second input. Advantageously, the first amplifier 525 generates a logic high when the reference ramp of the capacitor 505 is greater than the series combination of the voltage references 510 and 520.

The logic device 530 has a first input coupled to the first amplifier 525. The logic device 530 has a second input coupled to the clock source 535. The logic device 530 has a first output (Q) coupled to the second amplifier 540 and configured to be coupled to the duty cycle replication circuitry 240 of FIG. 2. The logic device 530 has a second output (QN) coupled to the switch 515. In the example of FIG. 5, the logic device 530 is a rising edge triggered set-reset (SR) flip-flop. Alternatively, the logic device 530 may be replaced and/or modified with alternate circuitry. Advantageously, the first output of the logic device 530 is approximately equal to a logic high when the reference ramp of the capacitor 505 is greater than the reference voltages 510 and 520 and the clock source 535 supplies a rising edge to the logic device 530. Advantageously, the first output of the logic device 530 is approximately equal to a logic low when the reference ramp of the capacitor 505 is less than the reference voltages 510 and 520.

The clock source 535 has a first terminal coupled to the logic device 530. The clock source 535 has a second terminal coupled to the common potential. The clock source 535 supplies a clock signal to the logic device 530. The period of the clock signal from the clock source 535 determines a period time of the reference clock. Advantageously, modifying the clock source 535 modifies a duty cycle of the reference clock.

The second amplifier 540 has a first input coupled to the logic device 530. The second amplifier 540 has a second input coupled to the common potential. The second amplifier 540 has a first output coupled to the common potential. The second amplifier 540 has a second output coupled to the capacitor 505, the switch 515, the first amplifier 525, and configured to be coupled to the interlock circuitry 220 of FIG. 2. The second amplifier 540 supplies a current from the common potential based on a voltage difference between the first and second inputs of the second amplifier 540. In the example of FIG. 5, the second amplifier 540 is controlled by the logic device 530.

In example operation, the logic device 530 closes (e.g., conducting) the switch 515 to hold the reference ramp of the capacitor 505 approximately equal to zero volts. In such an example operation, a rising edge from the clock source 535 sets the output of the logic device 530 opening (e.g., non-conducting) the switch 515. The second amplifier 540 supplies current to the capacitor 505 responsive to the rising edge of the clock source 535. The reference ramp of the capacitor 505 begins to increase responsive to the current from the second amplifier 540. In such example operations a rate of increase of the reference ramp is determined based on the amount of current sunk by the interlock circuitry 220. For example, an increase of the reference slows as current sourced by the interlock circuitry 220 increases.

The first amplifier 525 detects when the reference ramp is greater than a series combination of the reference voltages 510 and 520. The logic device 530 generates a falling edge of the reference clock responsive to the first amplifier 525 detecting the reference ramp is greater than the reference voltages 510 and 520. The logic device 530 closes the switch 515 responsive to the falling edge of the reference clock. Accordingly, the capacitor 505 is shorted and the reference ramp is set. Advantageously, increasing current being sunk by the interlock circuitry 220 increases the duration of time in which it takes for the reference ramp to be approximately equal to the combination of the reference voltages 510 and 520.

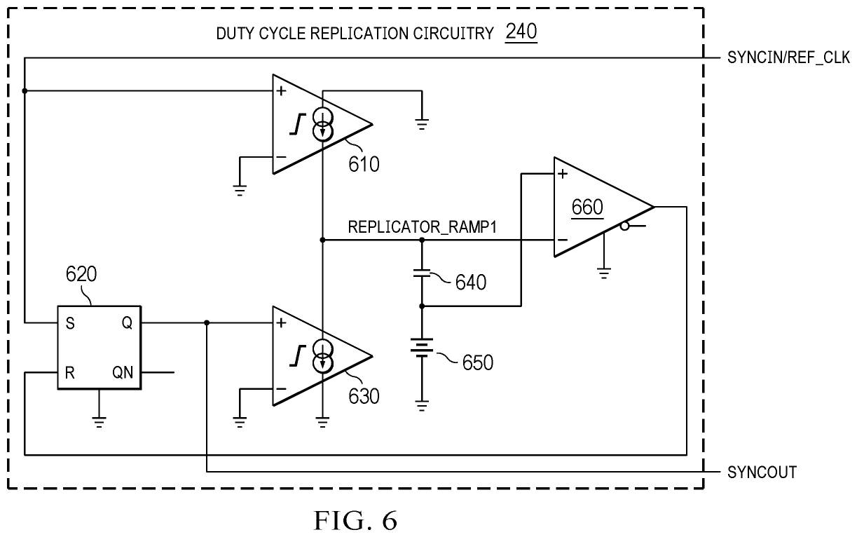

FIG. 6 is a schematic diagram of an example implementation of the duty cycle replication circuitry 240 of FIG. 2. In the example of FIG. 6, the duty cycle replication circuitry 240 includes a first example amplifier 610, an example logic device 620, a second example amplifier 630, an example capacitor 640, an example reference voltage 650, and a third example amplifier 660. The duty cycle replication circuitry 240 is configured to be coupled to the reference clock generation circuitry 230 of FIGS. 2 and 5 and the buffer circuitry 250 of FIG. 2. Alternatively, the example implementation of the duty cycle replication circuitry 240 of FIG. 3. In such an example, the duty cycle replication circuitry 240 is configured to be coupled to the detection circuitry 310 of FIG. 3 and the buffer circuitry 330 of FIG. 3.

The first amplifier 610 has a first input coupled to the logic device 620 and configured to be coupled to one of the reference clock generation circuitry 230 or the detection circuitry 310. The first amplifier 610 has a second input coupled to the common potential. The first amplifier 610 has a first output coupled to the common potential. The first amplifier 610 has a second output coupled to the second amplifier 630, the capacitor 640, and the third amplifier 660. The first amplifier 610 supplies a current to the second output based on a voltage of the first input. In some examples, the first amplifier 610 sources a current from the first output when a voltage of the first input is greater than a voltage of the second input. In the example of FIG. 6, the first amplifier 610 may be referred to as a transconductance amplifier.

The logic device 620 has a first input(S) coupled to the first amplifier 610 and configured to be coupled to one of the reference clock generation circuitry 230 or the detection circuitry 310. The logic device 620 has a second input (R) coupled to the third amplifier 660. The logic device 620 has an output coupled to second amplifier 630 and configured to be coupled to one of the buffer circuitries 250 or 330. In the example of FIG. 6, the logic device 620 is a rising edge triggered set-reset (SR) flip-flop. Alternatively, the logic device 620 may be replaced and/or modified with alternate circuitry.

The second amplifier 630 has a first input coupled to the logic device 620 and configured to be coupled to one of the buffer circuitries 250 or 330. The second amplifier 660 has a second input coupled to the common potential. The second amplifier 630 has a first output coupled to the first amplifier 610, the capacitor 640, and the third amplifier 660. The second amplifier 630 has a second output coupled to common potential. The second amplifier 630 sources a current from the first output based on a voltage of the first input. In some examples, the second amplifier 630 sources a current from the first output when a voltage of the first input is greater than a voltage of the second input. In the example of FIG. 6, the second amplifier 630 may be referred to as a transconductance amplifier.

The capacitor 640 has a first terminal coupled to the amplifiers 610, 630, and 660. The capacitor 640 has a second terminal coupled to the reference voltage 650 and the third amplifier 660. The capacitor 640 generates a replicator ramp based on the current being sourced and/or sunk by the amplifiers 610 and 630. The replicator ramp is a triangle waveform having a ramp up and a ramp down durations. The ramp up and the ramp down durations are proportional to the duty cycle of a signal at the inputs of the first amplifier 610 and the logic device 620. The ramp up and ramp down durations increase as the duty cycle of a signal coupled to the first amplifier 610 and logic device 620 increases. The first amplifier 610 constructs the ramp up of the replicator ramp by supplying a current to the capacitor 640 responsive to the first amplifier 610 receiving an input. The second amplifier 630 constructs the ramp down of the replicator ramp by sinking a current from the capacitor 640 responsive to the logic device 620 receiving an input. The capacitor 640 supplies the replicator ramp to the third amplifier 660.

The reference voltage 650 is coupled to the capacitor 640 and the third amplifier 660. The reference voltage 650 is a DC voltage configured to offset the capacitor 640 and the third amplifier 660.

The third amplifier 660 has a first input coupled to amplifiers 610 and 630 and the capacitor 640. The third amplifier 660 has a second input coupled to the capacitor 640 and the reference voltage 650. The third amplifier 660 has an output coupled to the logic device 620. The third amplifier 660 sets a voltage of the output based on a voltage difference between the first and second inputs. In some examples, the third amplifier 660 sets the output to a voltage approximately equal to a logic high when a voltage of the first input is greater than a voltage of the second input. In the example of FIG. 6, the third amplifier 660 may be referred to as a comparator.

In an example operation, the output of the third amplifier 660 is set based on the replicator ramp across the capacitor 640. In such an example operation, amplifiers 610 and 630 source and/or sink current to modify the replicator ramp of the capacitor 640. The first amplifier 610 supplies a reference current to the capacitor 640 while the reference clock from the reference clock generation circuitry is a logic high. The third amplifier 660 outputs a logic low responsive to the reference current from the first amplifier 610 increasing the reference ramp of the capacitor 640 to a voltage greater than and/or equal to the reference voltage 650.

In such example operations, the first amplifier 610 fails to supply a reference current to the capacitor 640 while the reference clock from the reference clock generation circuitry is a logic low. The logic device 620 outputs a logic high following the falling edge of the reference clock and the logic low from the third amplifier 660. The second amplifier 630 begins to source current from the capacitor 640 responsive to the logic low from the logic device 620. The replicator ramp of the capacitor 640 begins to decrease as the second amplifier 630 continues to sink current. The third amplifier 660 outputs a logic high responsive to the replicator ramp of the capacitor 640 decreasing below the reference voltage 650. The logic device 620 begins to output a logic low responsive to the logic high from the third amplifier 660 and the logic low of the reference clock.

Advantageously, the current supplied to the capacitor 640 by the first amplifier 610 is approximately equal to the current sourced by the second amplifier 630. Advantageously, the duration at which the reference clock signal causes the first amplifier to supply the reference current is approximately equal to the duration at which the logic device 620 causes the second amplifier 630 to sink the reference current. Advantageously, the output of the duty cycle replication circuitry 240 has a rising edge at a time approximately equal to a falling edge of the reference clock from the reference clock generation circuitry 230. Advantageously, a duty cycle of the output of the duty cycle replication circuitry 240 is approximately equal to the duty cycle of the reference clock from the reference clock generation circuitry 230.

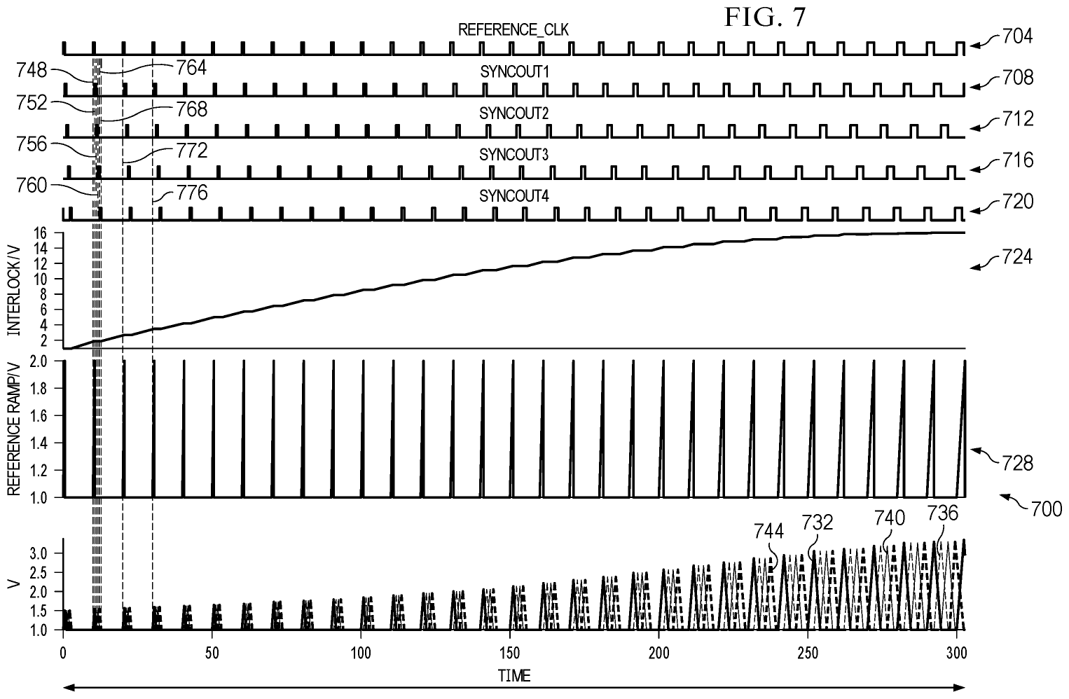

FIG. 7 is a timing diagram 700 of an example operation of the clock generation circuitries 135, 145, 155, and/or 165 of FIGS. 1-3. In the example of FIG. 7, the timing diagram 700 includes an example reference clock 704, a first example clock signal 708, a second example clock signal 712, a third example clock signal 716, a fourth example clock signal 720, an example interlock voltage 724, an example reference ramp 728, a first example replicator ramp 732, a second example replicator ramp 736, a third example replicator ramp 740, and a fourth example replicator ramp 744. In the example operations of the timing diagram 700, the clock generation circuitries 135, 145, 155, and 165 individually generate one of the clock signals 708-720.

The reference clock 704 represents the output of the reference clock generation circuitry 230 of FIGS. 2 and 5 over time. The first clock signal 708 represents the output of the primary clock generation circuitry over time. The second clock signal 712 represents the output of the first secondary clock generation circuitry 145 over time. The third clock signal 716 represents the output of the second secondary clock generation circuitry 155 over time. The fourth clock signal 720 represents the output of the third secondary clock generation circuitry 165 over time.

The interlock voltage 724 represents the voltage at the capacitor 445 of FIG. 4 of the interlock circuitry 220 of FIGS. 2 and 4 over time. The reference ramp 728 represents the voltage at the capacitor 505 of FIG. 5 over time. The replicator ramps 732-744 represent the voltage at the capacitor 640 for an occurrence of the duty cycle replication circuitry 240 of FIGS. 2 and 6 in each of the clock generation circuitries 135, 145, 155, and/or 165. For example, the first replicator ramp 732 represents the voltage at the capacitor 640 in the primary clock generation circuitry 135 while the second replicator ramp 736 represents the voltage at the capacitor 640 in an instance of the duty cycle replication circuitry 240 in the first secondary clock generation circuitry 145. In such examples, the third replicator ramp 740 represents the voltage at the capacitor 640 in an instance of the duty cycle replication circuitry 240 in the second secondary clock generation circuitry 155 and the second replicator ramp 736 represents the voltage at the capacitor 640 in an instance of the duty cycle replication circuitry 240 in the third secondary clock generation circuitry 165.

At a first time 748, the interlock circuitry 220 begins to source a current from the reference clock generation circuitry 230 responsive to the interlock voltage 724 being set to a first value. At the first time 748, the reference ramp 728 begins to increase as the interlock circuitry 220 sinks a current from the capacitor 505. At the first time 748, the reference clock generation circuitry 230 generates a rising edge on the reference clock 704. At the first time 748, the first replicator ramp 732 begins to increase responsive to the rising edge of the reference clock 704.

Following the first time 748, the second amplifier 540 of FIG. 5 begins to supply a current to the capacitor 505 and the interlock circuitry 220. Once the second amplifier 540 begins to supply a current to the capacitor 505 and the interlock circuitry 220, the reference ramp 728 begins to decrease.

At a second time 752, the reference clock generation circuitry 230 generates a falling edge on the reference clock 704 responsive to reference ramp 728 being approximately equal to zero. At the second time 752, the first replicator ramp 732 begins to decrease responsive to the falling edge of the reference clock 704. At the second time 752, the duty cycle replication circuitry 240 generates a rising edge on the first clock signal 708 responsive to the falling edge of the reference clock 704 setting the output of the logic device 620 of FIG. 6. At the second time 752, the second replicator ramp 736 begins to increase responsive to the rising edge of the first clock signal 708.

At a third time 756, the duty cycle replication circuitry 240 of the primary clock generation circuitry 135 generates a falling edge on the first clock signal 708 responsive to first replicator ramp 732 being approximately equal to zero. At the third time 756, the second replicator ramp 736 begins to decrease responsive to the falling edge of the first clock signal 708. At the third time 756, an instance of the duty cycle replication circuitry 240 of the first secondary clock generation circuitry 145 generates a rising edge on the second clock signal 712 responsive to the falling edge of the first clock signal 708 setting the output of the logic device 620. At the third time 756, the third replicator ramp 740 begins to increase responsive to the rising edge of the second clock signal 712.

At a fourth time 760, an instance of the duty cycle replication circuitry 240 of the first secondary clock generation circuitry 145 generates a falling edge on the second clock signal 712 responsive to second replicator ramp 736 being approximately equal to zero. At the fourth time 760, the third replicator ramp 740 begins to decrease responsive to the falling edge of the second clock signal 712. At the fourth time 760, an instance of the duty cycle replication circuitry 240 of the second secondary clock generation circuitry 155 generates a rising edge on the third clock signal 716 responsive to the falling edge of the second clock signal 712 setting the output of the logic device 620. At the fourth time 760, the fourth replicator ramp 744 begins to increase responsive to the rising edge of the third clock signal 716.

At a fifth time 764, an instance of the duty cycle replication circuitry 240 of the second secondary clock generation circuitry 155 generates a falling edge on the third clock signal 716 responsive to third replicator ramp 740 being approximately equal to zero. At the fifth time 764, the fourth replicator ramp 744 begins to decrease responsive to the falling edge of the third clock signal 716. At the fifth time 764, an instance of the duty cycle replication circuitry 240 of the third secondary clock generation circuitry 165 generates a rising edge on the fourth clock signal 720 responsive to the falling edge of the third clock signal 716 setting the output of the logic device 620.

At a sixth time 768, an instance of the duty cycle replication circuitry 240 of the third secondary clock generation circuitry 165 generates a falling edge on the fourth clock signal 720 responsive to fourth replicator ramp 744 being approximately equal to zero. At the sixth time 768, the interlock voltage 724 begins to increase responsive to the falling edge of the fourth clock signal 720.

At a seventh time 772, the clock source 535 of FIG. 5 sets the logic device 530 of FIG. 5 which generates a rising edge on the reference clock 704. The voltage increase of the interlock voltage 724 between the time 768 and 772 increases the duty cycle of the reference clock 704. Advantageously, the duty cycle replication circuitry 240 replicates the increased duty cycle to generate the clock signals 708-720.

At an eighth time 776, a second increase in the interlock voltage 724 further increases the duty cycle of the reference clock 704 and the clock signals 708-720. However, the increase in the duty cycle of the reference clock 704 and the clock signals 708-720 following the eighth time 776 is less than the increase following the seventh time 772. Advantageously, the interlock voltage 724 continues to increase until the reference clock signal is approximately equal to the fourth clock signal 720. In some examples, the number of secondary clock generation circuitries may be modified to generate a plurality of clock signals of different phases. In such examples, the secondary clock generation circuitry coupled to the primary clock generation circuitry generates a clock signal approximately equal to the reference clock 704.

Advantageously, the clock generation circuitries 135, 145, 155, and 165 dynamically adjust the duty cycle of the clock signals 708-720. Advantageously, the primary clock generation circuitry 135 dynamically adjusts a duty cycle of the reference clock 704 to compensate for a failure of one or more of the secondary clock generation circuitries 145, 155, and/or 165. In some examples, detection circuitry (e.g., the detection circuitry 210 of FIG. 2 and/or 310 of FIG. 2) determine a failure of one or more of the clock generation circuitries 135, 145, 155, and/or 165. In such examples, the clock generation circuitries 135, 145, 155, and/or 165 may be coupled to bypass the failing one or more of the clock generation circuitries 135, 145, 155, and/or 165. Advantageously, the primary clock generation circuitry 135 adjusts the duty cycle of the clock signals 708-720 based on the new configuration.

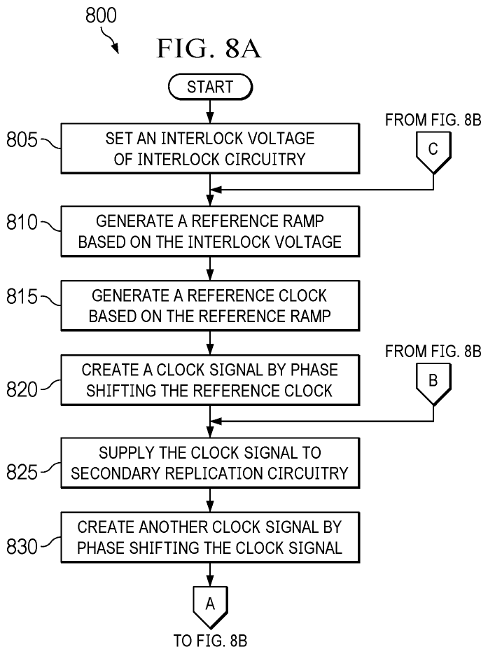

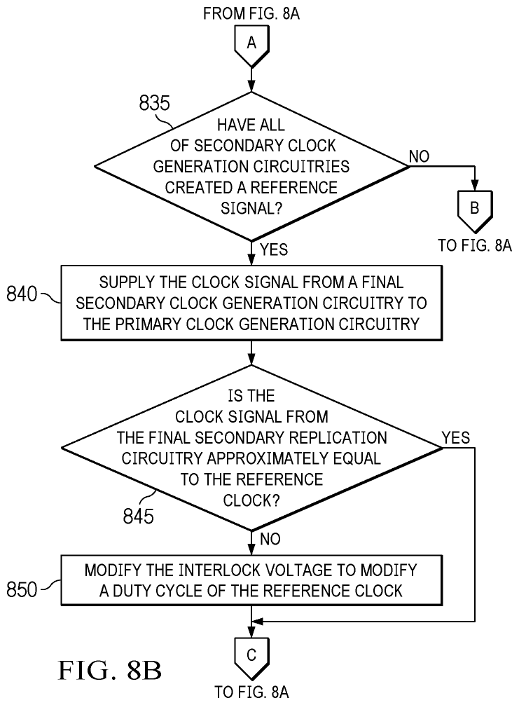

FIGS. 8A and 8B form a flowchart representative of example operations 800 that may be executed, instantiated, and/or performed by the primary and secondary clock generation circuitries 135, 145, 155 and/or 165 of FIGS. 1-3 to generate a plurality of clock signals of different phases. The operations 800 begin at Block 805 wherein, amplifiers 435 and 440 of FIG. 4 set an interlock voltage (e.g., the interlock voltage 724 of FIG. 7) of the interlock circuitry 220 of FIGS. 2 and 4. In some examples, the amplifiers 435 and 440 increase the interlock voltage 724 based on a comparison of an input from the detection circuitry 210 compared to the output of the primary clock generation circuitry 135 (e.g., the first clock signal 708). In such examples, the amplifiers 435 and 440 increase the interlock voltage 724 until a rising edge of the first clock signal 708.

The reference clock generation circuitry 230 of FIGS. 2 and 5 generates a reference ramp (e.g., the reference ramp 728 of FIG. 7) based on the interlock voltage. (Block 810). In some examples, the interlock voltage corresponds to a magnitude of current being sourced by the third amplifier 455 of FIG. 4. In such examples, the amount of current the interlock circuitry 220 sources from the reference clock generation circuitry 230 is proportional to the interlock voltage. The reference clock generation circuitry 230 generates the reference ramp based on the current being sourced by the interlock circuitry 220.

The reference clock generation circuitry 230 generates a reference clock (e.g., the reference clock 704 of FIG. 7) based on the reference ramp. (Block 815). In some examples. the reference clock generation circuitry 230 generates a reference clock based on the reference ramp and the clock source 535 of FIG. 5. In such examples, the clock source 535 controls a cycle time of the clock signals 708-720 of FIG. 7. Accordingly, the reference clock generation circuitry 230 generates a rising edge on the reference clock based on a rising edge of the clock source 535. The reference clock generation circuitry 230 generates a falling edge on the reference clock based on the reference ramp.

The duty cycle replication circuitry 240 of FIGS. 2 and 6 creates a clock signal (e.g., the first clock signal 708 of FIG. 7) by phase shifting the reference clock. (Block 820). In some examples, the duty cycle replication circuitry 240 generates a replicator ramp (e.g., the replicator ramps 732-744 of FIG. 7) based on the reference clock from the reference clock generation circuitry 230. In such examples, a rising edge of the replicator ramp corresponds to a duty cycle of the reference clock. For example, the logic device 620 generates the first clock signal 708 using the fall time of the first replicator ramp 732. Advantageously, the duty cycle replication circuitry 240 generates a clock signal with a duty cycle approximately equal to the duty cycle of the reference clock. Advantageously, the rising edge of the clock signal from the duty cycle replication circuitry 240 occurs at a time approximately equal to a falling edge of the reference clock.

The buffer circuitry 250 supplies the primary clock signal to secondary clock generation circuitry (e.g., the secondary clock generation circuitries 145, 155, and/or 165). (Block 825). In some examples, the buffer circuitry 250 supplies the primary clock signal to the first secondary clock generation circuitry 145 and the interlock circuitry 220.

An instance of the duty cycle replication circuitry 240 of one of the secondary clock generation circuitries 145, 155, and/or 165 creates another clock signal (e.g., one of the clock signals 712-720 of FIG. 7) by phase shifting the clock signal. (Block 830). In some examples, the duty cycle replication circuitry 240 generates a replicator ramp (e.g., the replicator ramps 732-744) based on one of the clock signals 708-720. In such examples, a rising edge of the replicator ramp corresponds to a duty cycle of the supplied clock signal and the reference clock. For example, the logic device 620 generates the second clock signal 712 using the fall time of the second replicator ramp 736.

Turning now to FIG. 8B, the primary clock generation circuitry 135 determines if all of the secondary clock generation circuitries (e.g., the secondary clock generation circuitries 145, 155, and 165) have created a clock signal. (Block 835). In some examples, the primary clock generation circuitry 135 determines that all of the secondary clock generation circuitries 145, 155, and 165 have created a clock signal responsive to receiving an input clock signal from a final secondary clock generation circuitry (e.g., the third secondary clock generation circuitry).

If the primary clock generation circuitry 135 determines that not all of the secondary clock generation circuitries have created a clock signal (e.g., Block 835 returns a result of NO), control proceeds to Block 825. If the primary clock generation circuitry 135 determines that all of the secondary clock generation circuitries have created a clock signal (e.g., Block 835 returns a result of YES), the buffer circuitry 330 of FIG. 3 supplies the clock signal from a final secondary clock generation circuitry (e.g., the third secondary clock generation circuitry 165) to the primary clock generation circuitry (e.g., the primary clock generation circuitry 135). (Block 840).

The interlock circuitry 220 determines if the clock signal from the final secondary clock generation circuitry (e.g., the fourth clock signal 720) is approximately equal to the reference clock (e.g., the reference clock 704). (Block 845). In some examples, the interlock circuitry 220 compares a falling edge of the clock signal from the third secondary clock generation circuitry 165 to a rising edge of the clock signal from the primary clock generation circuitry 135. In such examples, the interlock circuitry 220 determines the fourth clock signal 720 is approximately equal to the reference clock 704 when the rising edge of the first clock signal 708 occurs at a time approximately equal to the falling edge of the fourth clock signal 720.

If the interlock circuitry 220 determines the clock signal from the final secondary clock generation circuitry is approximately equal to the reference clock (e.g., Block 845 returns a result of YES), control proceeds to Block 810. If the interlock circuitry 220 determines the clock signal from the final secondary clock generation circuitry is not approximately equal to the reference clock (e.g., Block 845 returns a result of NO), the interlock circuitry 220 modifies the interlock voltage to modify a duty cycle of the reference clock. (Block 850). In some examples, the amplifiers 435 and/or 440 increase the interlock voltage for a duration of time between a falling edge of the fourth clock signal 720 and a rising edge of the first clock signal 708. Control proceeds to return to block 810.

Although example processes are described with reference to the flowchart illustrated in FIGS. 8A and 8B, many other methods of generating a multi-phase clock may alternatively be used in accordance with teachings of this disclosure. For example, the order of execution of the blocks may be changed, and/or some of the blocks described may be changed, eliminated, or combined. Similarly, additional operations may be included in the manufacturing process before, in between, or after the blocks shown in the illustrated examples.

In this description, the term “and/or” (when used in a form such as A, B and/or C) refers to any combination or subset of A, B, C, such as: (a) A alone; (b) B alone; (c) C alone; (d) A with B; (c) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described for methods and apparatus for multi-phase clock generation. Described systems, apparatus, articles of manufacture, and methods are accordingly directed to one or more improvement(s) in the operation of a machine such as a computer or other electronic and/or mechanical device.

The following claims are hereby incorporated into this Detailed Description by this reference. Although certain example systems, apparatus, articles of manufacture, and methods have been described herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
first clock generation circuitry including:
interlock circuitry having a terminal;
reference clock generation circuitry having a first terminal and a second terminal, the first terminal of the reference clock generation circuitry coupled to the terminal of the interlock circuitry;
first duty cycle replication circuitry having a first terminal and a second terminal, the first terminal of the first duty cycle replication circuitry coupled to the second terminal of the reference clock generation circuitry; and
buffer circuitry having a first terminal and a second terminal, the first terminal of the buffer circuitry coupled to the second terminal of the first duty cycle replication circuitry; and
second clock generation circuitry including:
detection circuitry having a first terminal and a second terminal, the first terminal of the detection circuitry coupled to the second terminal of the buffer circuitry;
second detection circuitry having a first terminal and a second terminal, the first terminal of the second detection circuitry coupled to the second terminal of the detection circuitry; and
second duty cycle replication circuitry having a terminal coupled to the second terminal of the second detection circuitry.

2. The apparatus of claim 1, wherein the buffer circuitry is first buffer circuitry, the terminal of the interlock circuitry is a first terminal of the interlock circuitry, the terminal of the second duty cycle replication circuitry is a first terminal of the second duty cycle replication circuitry, the apparatus further including second buffer circuitry having a first terminal and a second terminal, the first terminal of the second buffer circuitry coupled to a second terminal of the second duty cycle replication circuitry, and the second terminal of the second buffer circuitry coupled to a second terminal of the interlock circuitry.

3. The apparatus of claim 1, wherein the interlock circuitry includes:
a first logic gate having a first input, a second input, and an output, the first input of the first logic gate coupled to the second terminal of the buffer circuitry;
a second logic gate having a first input, a second input, and an output, the first input coupled to the output of the first logic gate;
a logic device having an input and an output, the input of the logic device coupled to the second input of the first logic gate, the output of the logic device coupled to the second input of the second logic gate;
a first amplifier having an input and an output, the input of the first amplifier coupled to the output of the second logic gate; and
a second amplifier having an input and an output, the input of the second amplifier coupled to the output of the first amplifier, the output of the second amplifier coupled to the first terminal of the reference clock generation circuitry.

4. The apparatus of claim 3, wherein the input of the second amplifier is a first input, the second amplifier further having a second input, the interlock circuitry further including a capacitor having a first terminal and a second terminal, the first terminal of the capacitor is coupled to the output of the first amplifier and the first input of the second amplifier, the second terminal of the capacitor coupled to the second input of the second amplifier.

5. The apparatus of claim 1, wherein the reference clock generation circuitry includes:
a capacitor having a first terminal and a second terminal, the first terminal of the capacitor coupled to the terminal of the interlock circuitry;
a switch having a first terminal, a second terminal, and a third terminal, the first terminal of the switch coupled to the terminal of the interlock circuitry and the first terminal of the capacitor, the second terminal of the switch coupled to the second terminal of the capacitor;
a first amplifier having an input and an output, the input of the first amplifier coupled to the terminal of the interlock circuitry, the first terminal of the capacitor, and the first terminal of the switch;
a logic device having an input, a first output, and a second output, the input of the logic device coupled to the output of the first amplifier, the first output of the logic device coupled to the third terminal of the switch; and
a second amplifier having an input and an output, the input of the second amplifier coupled to the second output of the logic device and the first terminal of the first duty cycle replication circuitry, the output of the second amplifier coupled to the terminal of the interlock circuitry, the first terminal of the capacitor, the first terminal of the switch, and the input of the first amplifier.

6. The apparatus of claim 1, wherein the first duty cycle replication circuitry includes:
a first amplifier having an input and an output, the input of the first amplifier coupled to the second terminal of the reference clock generation circuitry;
a logic device having a first input, a second input, and an output, the first input of the logic device coupled to the input of the first amplifier, the output of the logic device coupled to the input of the buffer circuitry;
a second amplifier having an input and an output, the input of the second amplifier coupled to the output of the logic device, the output of the second amplifier coupled to the output of the first amplifier; and
a third amplifier having an input and an output, the input of the third amplifier coupled to the output of the first amplifier and the output of the second amplifier, the output of the third amplifier coupled to the second input of the logic device.

7. The apparatus of claim 1, the terminal of the interlock circuitry is a first terminal of the interlock circuitry, the terminal of the second duty cycle replication circuitry is a first terminal of the second duty cycle replication circuitry, the interlock circuitry further having a second terminal, the second duty cycle replication circuitry further having a second terminal, the apparatus further including third clock generation circuitry having a first terminal and a second terminal, the first terminal of the third clock generation circuitry coupled to the first terminal of the third clock generation circuitry coupled to the second terminal of the second duty cycle replication circuitry, the second terminal of the third clock generation circuitry coupled to the second terminal of the interlock circuitry.

8. A system comprising:
interlock circuitry including:
a first logic gate having an input, and an output;
a second logic gate having a first input, a second input, and an output, the first input of the second logic gate coupled to the output of the first logic gate;
a logic device having an input and an output, the input of the logic device coupled to the input of the first logic gate, the output of the logic device coupled to the second input of the second logic gate;
a first amplifier having an input and an output, the input of the first amplifier coupled to the output of the second logic gate; and
a second amplifier having an input and an output, the input of the second amplifier coupled to the output of the first amplifier;
reference clock generation circuitry having a first terminal and a second terminal, the first terminal of the reference clock generation circuitry coupled to the output of the second amplifier; and
duty cycle replication circuitry having a terminal coupled to the second terminal of the reference clock generation circuitry.

9. The system of claim 8, wherein the input of the second amplifier is a first input, the second amplifier further having a second input, the interlock circuitry further including a capacitor having a first terminal and a second terminal, the first terminal of the capacitor is coupled to the output of the first amplifier and the first input of the second amplifier, the second terminal of the capacitor coupled to the second input of the second amplifier.

10. The system of claim 8, wherein the logic device is a first logic device, the reference clock generation circuitry includes:
a capacitor having a first terminal and a second terminal, the first terminal of the capacitor coupled to the output of the second amplifier;
a switch having a first terminal, a second terminal, and a third terminal, the first terminal of the switch coupled to the output of the second amplifier and the first terminal of the capacitor, the second terminal of the switch coupled to the second terminal of the capacitor;
a third amplifier having an input and an output, the input of the third amplifier coupled to the output of the second amplifier, the first terminal of the capacitor, and the first terminal of the switch;
a second logic device having an input, a first output, and a second output, the input of the second logic device coupled to the output of the third amplifier, the first output of the second logic device coupled to the third terminal of the switch; and
a fourth amplifier having an input and an output, the input of the fourth amplifier coupled to the second output of the second logic device and the terminal of the duty cycle replication circuitry, the output of the fourth amplifier coupled to the output of the second amplifier, the first terminal of the capacitor, the first terminal of the switch, and the input of the third amplifier.

11. The system of claim 8, wherein the logic device is a first logic device, the duty cycle replication circuitry includes:
a third amplifier having an input and an output, the input of the third amplifier coupled to the second terminal of the reference clock generation circuitry;
a second logic device having a first input, a second input, and an output, the first input of the second logic device coupled to the input of the third amplifier;
a fourth amplifier having an input and an output, the input of the fourth amplifier coupled to the output of the second logic device, the output of the fourth amplifier coupled to the output of the third amplifier; and
a fifth amplifier having an input and an output, the input of the fifth amplifier coupled to the output of the third amplifier and the output of the fourth amplifier, the output of the fifth amplifier coupled to the second input of the second logic device.

12. The system of claim 8, wherein the input of the first logic gate is a first input, the terminal of the duty cycle replication circuitry is a first terminal, the first logic gate further having a second input, the duty cycle replication circuitry further having a second terminal, the system further including buffer circuitry having a first terminal and a second terminal, the first terminal of the buffer circuitry coupled to the second terminal of the duty cycle replication circuitry, the second terminal of the buffer circuitry coupled to the second input of the first logic gate.

13. The system of claim 12, wherein the system further includes secondary clock generation circuitry having a first terminal and a second terminal, the first terminal of the secondary clock generation circuitry coupled to the second terminal of the buffer circuitry, the second terminal of the secondary clock generation circuitry adaptive to be coupled to the input of the first logic gate and the input of the logic device.

14. The system of claim 8, wherein the system further includes detection circuitry having a terminal coupled to the input of the first logic gate and the input of the logic device.

15. A device comprising:
interlock circuitry having a terminal;
reference clock generation circuitry including:
a capacitor having a first terminal and a second terminal, the first terminal of the capacitor coupled to the terminal of the interlock circuitry;
a switch having a first terminal, a second terminal, and a third terminal, the first terminal of the switch coupled to the terminal of the interlock circuitry and the first terminal of the capacitor, the second terminal of the switch coupled to the second terminal of the capacitor;
a first amplifier having an input and an output, the input of the first amplifier coupled to the terminal of the interlock circuitry, the first terminal of the capacitor, and the first terminal of the switch;
a logic device having an input, a first output, and a second output, the input of the logic device coupled to the output of the first amplifier, the first output of the logic device coupled to the third terminal of the switch; and
a second amplifier having an input and an output, the input of the second amplifier coupled to the second output of the logic device, the output of the second amplifier coupled to the terminal of the interlock circuitry, the first terminal of the capacitor, the first terminal of the switch, and the input of the first amplifier; and
duty cycle replication circuitry having a terminal coupled to the second output of the logic device.

16. The device of claim 15, wherein the logic device is a first logic device, the interlock circuitry includes:
a first logic gate having an input and an output;
a second logic gate having a first input, a second input, and an output, the first input coupled to the output of the first logic gate;
a second logic device having an input and an output, the input of the second logic device coupled to the input of the first logic gate, the output of the second logic device coupled to the second input of the second logic gate;
a third amplifier having an input and an output, the input of the third amplifier coupled to the output of the second logic gate; and
a fourth amplifier having an input and an output, the input of the fourth amplifier coupled to the output of the third amplifier, the output of the fourth amplifier coupled to the first terminal of the capacitor, the first terminal of the switch, and the input of the first amplifier.

17. The device of claim 16, wherein the input of the fourth amplifier is a first input, the fourth amplifier further having a second input, the interlock circuitry further including a capacitor having a first terminal and a second terminal, the first terminal of the capacitor is coupled to the output of the third amplifier and the first input of the fourth amplifier, the second terminal of the capacitor coupled to the second input of the fourth amplifier.

18. The device of claim 15, wherein the logic device is a first logic device, the duty cycle replication circuitry includes:
a third amplifier having an input and an output, the input of the third amplifier coupled to the second output of the first logic device and the input of the second amplifier;
a second logic device having a first input, a second input, and an output, the first input of the second logic device coupled to the input of the third amplifier;
a fourth amplifier having an input and an output, the input of the fourth amplifier coupled to the output of the second logic device, the output of the fourth amplifier coupled to the output of the third amplifier; and
a fifth amplifier having an input and an output, the input of the fifth amplifier coupled to the output of the third amplifier and the output of the fourth amplifier, the output of the fifth amplifier coupled to the second input of the second logic device.

19. The device of claim 18, wherein the terminal of the interlock circuitry is a first terminal, the interlock circuitry further having a second terminal, the device includes buffer circuitry having a first terminal and a second terminal, the first terminal of the buffer circuitry coupled to the output of the second logic device and the input of the fourth amplifier, the second terminal of the buffer circuitry coupled to the second terminal of the interlock circuitry.

20. The device of claim 15, wherein terminal of the interlock circuitry is a first terminal, the interlock circuitry further having a second terminal, the device includes detection circuitry having a terminal coupled to the second terminal of the interlock circuitry.
